(19) United States
(12) Patent Application Publication
(10) Pub. No.: US 2026/0305250 A1
(43) Pub. Date: Oct. 1, 2026

(54) TEMPERATURE CONTROL MEMBER AND ELECTROSTATIC CHUCK DEVICE

(71) Applicant: SUMITOMO OSAKA CEMENT CO., LTD., Tokyo (JP)

(72) Inventors: Megumi OOTOMO, Tokyo (JP); Nobuhiro HIDAKA, Tokyo (JP); Kenta YASUNO, Tokyo (JP)

(73) Assignee: SUMITOMO OSAKA CEMENT CO., LTD., Tokyo (JP)

(21) Appl. No.: 19/163,388

(22) PCT Filed: Apr. 19, 2024
(86) PCT No.: PCT/JP2024/015641

§ 371 Date: Sep. 9, 2025

(30) Foreign Application Priority Data
Apr. 20, 2023 (JP) 2023-069432

(51) Int. Cl. H10P 72/72; H01J 37/32

(52) U.S. Cl. CPC H10P 72/722; H01J 37/32724; H01J 2237/2007

(57) ABSTRACT

Provided is a temperature control member that is formed of a conductive ceramic as a forming material, including a flow channel through which a heat medium flows, in which the conductive ceramic is formed of a high thermal conductive material and a conductive material, and a volume ratio between the high thermal conductive material and the conductive material is 10:90 to 90:10, and a thermal expansion coefficient of the conductive ceramic at 800° C. is 10×10⁻⁶/K or lower.

### TECHNICAL FIELD

The present invention relates to a temperature control member and an electrostatic chuck device. This application claims priority based on Japanese Patent Application No. 2023-069432 filed on Apr. 20, 2023, the content of which is incorporated herein by reference.

### BACKGROUND ART

A temperature control member such as a heat exchanger including a flow channel can perform heat exchange with another member in contact with a flow channel member by allowing a heat medium to flow through the flow channel. As a result, a temperature of the other member in contact with the temperature control member can be adjusted. In the present specification, “heat medium” includes both of a heat medium for heating (or a heating medium) and a heat medium for cooling (or a coolant).

For example, in a semiconductor manufacturing process for manufacturing a semiconductor such as an IC, an LSI, or a VLSI, an electrostatic chuck device that electrostatically adsorbs a plate-shaped sample in a case of carrying out a plasma treatment on the plate-shaped sample such as a silicon wafer is used. In the electrostatic chuck device, by using a metal base including a flow channel through which a heat medium flows as the temperature control member and allowing a coolant to flow through the flow channel, an electrostatic chuck member that is supported by the base is cooled. (for example, refer to Patent Literatures 1 and 2).

### CITATION LIST

### Patent Literature

Patent Literature No. 1: Japanese Laid-open Patent Publication No. 2014-131015
Patent Literature No. 2: Japanese Laid-open Patent Publication No. 2023-1603

### SUMMARY OF INVENTION

### Technical Problem

In the electrostatic chuck device, with the diversification of semiconductor processes, the temperature of a plate-shaped sample during the treatment is required to be controlled within a wider temperature range than in the related art. As a result of diversification of processes where the device is used, various devices including the temperature control member are also required to be able to be used in a wide temperature range from a high temperature to a low temperature.

In the metal temperature control member used in Patent Literatures 1 and 2, thermal conduction is excellent, and thus heat transfer is easy. However, in the metal temperature control member, a volume change is likely to occur together with a temperature change of the member, and strain is likely to be generated at an interface with an object in contact with the temperature control member (object of temperature control). The generated strain may cause breakage of the device, and thus improvement is required.

The present invention has been made under these circumstances, and an object thereof is to provide a novel temperature control member where an excellent temperature control can be performed. In addition, another object is to provide an electrostatic chuck device including the temperature control member.

### Solution to Problem

In order to achieve the above-described object, one aspect of the present invention includes the following aspects.

[1] A temperature control member that is formed of a conductive ceramic as a forming material, including a flow channel through which a heat medium flows, in which the conductive ceramic is formed of a high thermal conductive material and a conductive material, and a volume ratio between the high thermal conductive material and the conductive material is 10:90 to 90:10, and a thermal expansion coefficient of the conductive ceramic at 800° C. is 10×10⁻⁶/K or lower.

[2] The temperature control member according to [1], in which the high thermal conductive material is at least one selected from the group consisting of AlN, SiC, GaN, SiO₂, Al₂O₃, SmAlO₃, MgO, SiO₂, Si₃N₄, Al(OH)₃, MgO, Mg(OH)₂, BN, ZnO, BeO, B₄C, carbon, aluminum, copper, silver, and gold, and the conductive material is at least one selected from the group consisting of SiC, TiO₂, TIN, TiC, W, WC, Mo, MOC, MO₂C, TaC, TaN, NbC, VC, and C.

[3] The temperature control member according to [2], in which the high thermal conductive material is AlN, and the conductive material is either or both of TiN and Mo.

[4] The temperature control member according to [2], in which the high thermal conductive material is AlN, and the conductive material is Mo.

[5] The temperature control member according to [2], in which the high thermal conductive material is AlN, and the conductive material is TiN and Mo.

[6] An electrostatic chuck device including: the temperature adjusting member according to any one of [1] to [5]; and an electrostatic chuck member that is supported by the temperature adjusting member and includes a dielectric substrate and an internal electrode.

In addition, the present invention may have the following aspects. For example, a base of an electrostatic chuck device according to [A1] below may be the temperature control member according to [1].

[A1] An electrostatic chuck device including: an electrostatic chuck member including a dielectric substrate and an internal electrode; a base; and a joining layer formed of a metal material and configured to join the electrostatic chuck member and the base to each other, in which the dielectric substrate is formed of a ceramic, and the base is formed of, as a forming material, a conductive ceramic where a volume ratio between a high thermal conductive material and a conductive material is 30:70 to 60:40.

[A2] The electrostatic chuck device according to [A1], in which the high thermal conductive material is at least one selected from the group consisting of AlN, SiC, GaN, SiO₂, Al₂O₃, SmAlO₃, MgO, SiO₂, Si₃N₄, Al(OH)₃, MgO, Mg(OH)₂, BN, ZnO, BeO, B₄C, carbon, aluminum, copper, silver, and gold, and the conductive material is at least one selected from the group consisting of SiC, TiO₂, TIN, TIC, W, WC, MOC, MO₂C, TaC, TaN, NbC, VC, and C.

[A3] The electrostatic chuck device according to [A2], in which the high thermal conductive material is AlN, and the conductive material is TiN.

[A4] The electrostatic chuck device according to any one of [A1] to [A3], in which the joining layer includes: a stress relief layer; a first joining layer configured to join the stress relief layer and the electrostatic chuck member to each other; and a second joining layer configured to join the stress relief layer and the base to each other.

[A5] The electrostatic chuck device according to [A4], in which the stress relief layer is a metal foil that is formed of at least one metal selected from the group consisting of Cu, Al, Ti, Nb, and W, materials of the first joining layer and the second joining layer have a lower melting point than the material for forming the stress relief layer, and when a total volume of the first joining layer is represented by 100% by volume, the material of the first joining layer is an alloy that includes 50% by volume or more of Al or Ag and 0.02% by volume or more and 40% by volume or less of at least one metal selected from the group consisting of Ti, Zr, and Hf.

[A6] The electrostatic chuck device according to [A5], in which the first joining layer and the second joining layer are formed of the same material.

[A7] The electrostatic chuck device according to any one of [A1] to [A6], further includes: a supporting plate provided on a side of the base opposite to the electrostatic chuck member, in which the supporting plate is formed of a material having a higher Young's modulus than a material of the base.

### Advantageous Effects of Invention

According to the present invention, it is possible to provide a novel temperature control member where an excellent temperature control can be performed. In addition, it is also possible to provide an electrostatic chuck device including the temperature control member.

### BRIEF DESCRIPTION OF DRAWINGS

FIG. 1 is a schematic cross-sectional view illustrating a temperature control member and an electrostatic chuck device 1A according to a first embodiment.

FIG. 2 is a diagram illustrating an electrostatic chuck device 1B according to a second embodiment.

FIG. 3 is a scanning electron microscope (SEM) image illustrating a conductive ceramic plate used in Example 1.

FIG. 4 is a scanning electron microscope (SEM) image illustrating a conductive ceramic plate used in Example 4.

### DESCRIPTION OF EMBODIMENTS

### First Embodiment

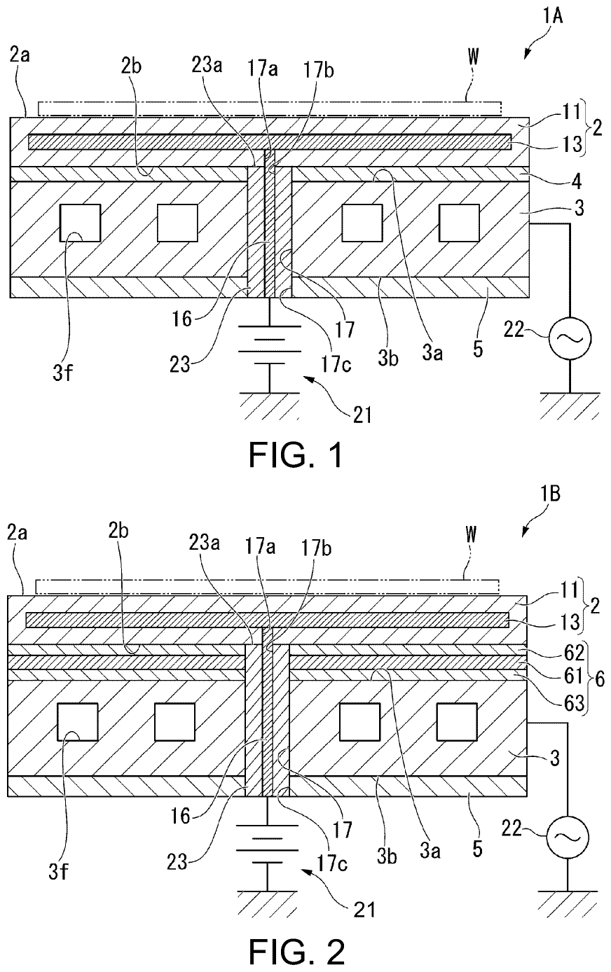

Hereinafter, a temperature control member and an electrostatic chuck device according to a first embodiment of the present invention will be described with reference to FIG. 1. The first embodiment and the second embodiment will be described in detail for easy understanding of the concept of the present invention, but the present invention is not limited thereto unless otherwise specified. For example, unless otherwise specified, conditions such as materials, amounts, kinds, numbers, sizes, shapes, positions, ratios, temperatures, and the like may be changed, added, or omitted as necessary.

### <<Temperature Control Member and Electrostatic Chuck Device>>

FIG. 1 is a schematic cross-sectional view illustrating a temperature control member and an electrostatic chuck device 1A according to a first embodiment. The electrostatic chuck device 1A includes an electrostatic chuck member 2, a base 3, a joining layer 4, a supporting plate 5, an insulator (insertion component) 23, and a feeding terminal 16. The electrostatic chuck member 2 and the base 3 are stacked through the joining layer 4. The base 3 corresponds to “temperature control member” according to the present invention.

In the present specification, a direction in which the electrostatic chuck member 2 and the base 3 are stacked will be referred to as a stacking direction. Further, a side of the base 3 where the electrostatic chuck member 2 is disposed will be referred to as “one side in the stacking direction”, and the opposite side thereof will be referred to as “another side in the stacking direction”. In addition, in the following description, assuming that an up-down direction is the stacking direction, each of units in the electrostatic chuck device 1A will be described. Note that the up-down direction described herein is merely a direction used for simplifying the description, and does not limit a position when the electrostatic chuck device 1A is used. The upper side corresponds to one side in the stacking direction and the lower side corresponds to the other side in the stacking direction.

### <Electrostatic Chuck Member>

The electrostatic chuck member 2 includes a dielectric substrate 11 and an adsorption electrode (internal electrode) 13 positioned inside the dielectric substrate 11. A placement surface 2a for adsorbing a wafer W is provided on an upper surface of the electrostatic chuck member 2. A focus ring surrounding the wafer W may be disposed outside the placement surface 2a of the electrostatic chuck member 2.

### (Dielectric Substrate)

It is preferable that the dielectric substrate 11 is formed of a ceramic having a sufficient mechanical strength and durability against corrosive gas and plasma thereof.

The ceramic forming the dielectric substrate 11 includes aluminum oxide (Al₂O₃) as a main component. “Main component” refers to a component that occupies 50% by volume or more with respect to the total volume. As necessary, aluminum oxide may occupy 60% by volume or more, 70% by volume or more, 80% by volume or more, 90% by volume or more, or 98% by volume or more with respect to the total volume. As the ceramic, for example, an aluminum oxide (Al₂O₃) sintered body, an aluminum oxide (Al₂O₃)-silicon carbide (SiC) composite sintered body, or the like is suitably used. In particular, from the viewpoints of dielectric characteristics, high corrosion resistance, plasma resistance, and heat resistance at a high temperature, the material forming the dielectric substrate 11 is preferably an Al₂O₃—SiC composite sintered body.

The dielectric substrate 11 has a circular shape or a substantially circular plate shape in a plan view. The dielectric substrate 11 includes: the placement surface 2a on which the wafer W is placed; and a back surface 2b that faces the side opposite to the placement surface 2a. In the placement surface 2a, for example, a plurality of protrusion portions (not illustrated) may be formed at predetermined intervals. In this case, the placement surface 2a supports the wafer W at tip portions of the plurality of protrusion portions. In the present specification, “plan view” refers to a field of view seen from a thickness direction (stacking direction) of the electrostatic chuck member 2.

### (Adsorption Electrode)

The adsorption electrode 13 is disposed inside the dielectric substrate 11. It is preferable that the adsorption electrode 13 extends in a plate shape along the placement surface 2a of the dielectric substrate 11. By applying a voltage, the adsorption electrode 13 generates an electrostatic adsorption force to hold the wafer W in the placement surface 2a of the dielectric substrate 11. The feeding terminal 16 for applying a direct current voltage to the adsorption electrode 13 is connected to the adsorption electrode 13.

The adsorption electrode 13 is preferably formed of a composite of an insulating material and a conductive material.

The insulating material in the adsorption electrode 13 is not particularly limited, and is preferably, for example, at least one selected from the group consisting of aluminum oxide (Al₂O₃), aluminum nitride (AlN), silicon nitride (Si₃N₄), yttrium (III) oxide (Y₂O₃), yttrium-aluminum-garnet (YAG), and SmAlO₃.

The conductive material in the adsorption electrode 13 is preferably at least one selected from the group consisting of molybdenum carbide (Mo₂C), molybdenum (Mo), tungsten carbide (WC), tungsten (W), tantalum carbide (TaC), tantalum (Ta), silicon carbide (SiC), carbon black, carbon nanotubes, and carbon nanofibers.

The thickness of the electrostatic chuck member 2 can be freely selected and is preferably 0.5 mm or more and 5 mm or less. When the thickness of the electrostatic chuck member 2 is 0.5 mm or more, the withstand voltage of the electrostatic chuck member 2 increases. In addition, when the thickness of the electrostatic chuck member 2 is 5 mm or less, the heat capacity of the electrostatic chuck member 2 is small. Therefore, the temperature of the plate-shaped sample, which is an object to be treated, is likely to be uniformly maintained during the plasma treatment.

### <Base>

The base 3 is a disk-shaped or substantially disk-shaped member in a plan view, and supports the electrostatic chuck member 2 from the lower side (other side in the stacking direction). On the base 3, a support surface 3a facing upward (one side in the stacking direction) and a lower surface 3b facing downward are provided. The support surface 3a faces the back surface 2b of the dielectric substrate 11 through the joining layer 4 in the up-down direction (stacking direction). The base 3 supports the electrostatic chuck member 2 on the support surface 3a. The thickness of the base 3 can be freely selected as necessary. For example, the thickness of the base 3 may be 20 mm to 50 mm.

In the base 3, a flow channel 3f for circulating a heat medium (coolant) is provided. The coolant flowing through the flow channel 3f can be freely selected, and water, He gas, N₂ gas, fluorine-based inert fluid, liquid nitrogen, oil, alcohol, or the like can be adopted. The flow channel 3f extends along the support surface 3a. The coolant in the flow channel 3f cools the entire base 3, and cools the electrostatic chuck member 2 through the support surface 3a.

The base 3 is connected to an external high-frequency power supply 22 through a matching box (not illustrated), and may also function as an internal electrode for generating a plasma.

The base 3 is formed of a conductive ceramic including a high thermal conductive material and a conductive material (hereinafter, also abbreviated as “conductive ceramic”) as a forming material. Specifically, in the material of the base 3, when the total volume of the base 3 is represented by 100% by volume, a volume ratio between the high thermal conductive material and the conductive material (volume of high thermal conductive material: volume of conductive material) is 10:90 to 90:10, preferably 20:80 to 80:20, more preferably 25:75 to 70:30, and still more preferably 30:70 to 60:40. As necessary, the volume ratio may be 15:85 to 35:65, 35:55 to 55:45, 55:45 to 75:25, or the like.

It is assumed that, by allowing the heat medium to flow through the flow channel 3f, frictional electrification occurs between the heat medium and the base 3. The charge generated this way adversely affects the process or the device, and thus is preferably erased rapidly. On the other hand, the forming material for the base 3 is the conductive ceramic such that the charge generated by the frictional electrification can be easily erased.

In addition, a thermal expansion coefficient of the conductive ceramic that is the material of the base 3 at 800° C. is 10×10⁻⁶/K (10 ppm/K) or less, preferably 9×10⁻⁶/K or lower, and more preferably 8×10⁻⁶/K or lower. By setting the thermal expansion coefficient of the base 3 to the above-described value, when the heat medium is allowed to flow through the base 3, a volume change of the base 3 caused by a temperature change of the base 3 can be suppressed. As a result, at an interface with the configuration (in the case of the electrostatic chuck device 1A, the joining layer 4) in contact with the base 3, strain is not likely to occur, and breakage of the device can be suppressed. The lower limit of the thermal expansion coefficient of the base 3 at 800° C. can be freely selected, and may be, for example, 5×10⁻⁶/K or higher, 6×10⁻⁶/K or higher, or 6.8×10⁻⁶/K or higher as necessary.

As the thermal expansion coefficient of the material of the base 3 at 800° C., a value of an average linear thermal expansion coefficient (CTE) when the material of the base 3 is subjected to a temperature change of 25° C. to 800° C. can be adopted.

The average linear thermal expansion coefficient (CTE) when the material of the base 3 (conductive ceramic) is subjected to a temperature change of 25° C. to 800° C. can be measured by a measuring device that is freely selected, for example, a thermal expansion measuring device (TD 5000 SA, manufactured by NETZSCH Japan K.K.). First, a measurement sample (test piece) formed of the conductive ceramic is changed from 25° C. to 800° C. at a temperature increase rate of 5° C./min, a length (L0) of the measurement sample at 25° C. and a length (L1) of the measurement sample at 800° C. are measured, and a change (AL) in the length of the measurement sample is measured. The average linear thermal expansion coefficient can be calculated by dividing AL by the length (L0) of the measurement sample at 25° C. to obtain a thermal expansion rate, and by dividing the thermal expansion rate by a temperature change width (ΔT=800° C.-25° C.).

That is, in the present embodiment, “the thermal expansion coefficient at 800° C.” can be calculated from {(L1−L0)/L0}/ΔT=(ΔL/L0)/ΔT.

The base 3 is formed of preferably a material having a thermal conductivity of 40 W/m·K or higher and more preferably a material having a thermal conductivity of 50 W/m·K or higher and 110 W/m·K or lower. The thermal conductivity may be 45 W/m·K or higher and 100 W/m·K or lower, 60 W/m·K or higher and 90 W/m·K or lower, or 70 W/m·K or higher and 80 W/m·K or lower, or the like as necessary. By setting the thermal conductivity to be in the above-described range, input heat can be effectively dissipated.

The conductive material can be freely selected, and is preferably at least one selected from the group consisting of SiC, TiO₂, TIN, TIC, W, WC, Mo, MOC, Mo₂C, TaC, TaN, NbC, VC, and C. Among these, from the viewpoint of excellent plasma resistance, TiN is preferable. From the viewpoint of high thermal conductivity, Mo or W is preferable. As the conductive material, TiN and Mo may be used alone or in combination thereof.

The high thermal conductive material can be freely selected, and is preferably at least one selected from the group consisting of AlN, SiC, GaN, SiO₂, Al₂O₃, SmAlO₃, MgO, SiO₂, Si₃N₄, Al(OH)₃, MgO, Mg(OH)₂, BN, ZnO, BeO, B₄C, carbon (C), aluminum, copper, silver, and gold. Among these, AlN is preferable from the viewpoints of high thermal conductivity and easy handling.

When SiC is used as the high thermal conductive material, a material other than SiC is selected as the conductive material. When SiC is used as the high thermal conductive material, for example, TiN can be selected as the conductive material. Likewise, when C is used as the high thermal conductive material, a material other than C is selected as the conductive material.

In addition, when the conductive material and the high thermal conductive material are combined from the above-described materials, it is preferable that the obtained material includes an inorganic oxide, an inorganic carbide, an inorganic nitride, and/or an inorganic carbonitride belonging to any of the conductive material and the high thermal conductive material. Among these, it is preferable that the material includes an inorganic oxide and/or an inorganic nitride. By including an inorganic oxide and/or an inorganic nitride, the obtained material is preferable as “conductive ceramic”.

As the material having conductivity and including a ceramic, a metal matrix composite (MMC) that is a composite material of a metal and a ceramic is also known. However, MMC is generally adjusted by using a method (metal cementation method, forging method) of adjusting a porous ceramic substrate and subsequently introducing molten metal such as Mg, Al, or Si into micropores of the ceramic substrate. Therefore, the metal in the MMC is limited to metal having a relatively low melting point. The metal may melt depending on use conditions of the temperature control member.

On the other hand, in the above-described conductive ceramic, as the conductive material, a high melting metal (Mo: a melting point of 2622° C., W: a melting point of 3407° C.) having a higher melting point of 1800° C. or higher compared to Mg (melting point: 650° C.), A1 (melting point: 660° C.), and Si (melting point: 1414° C.) used for MMC can be used. Therefore, the base 3 can be suitably used even at a high temperature.

The thermal expansion coefficient of the dielectric substrate 11 can be freely selected. When the main component of the dielectric substrate 11 is aluminum oxide and is used in combination with silicon carbide, the thermal expansion coefficient of the dielectric substrate 11 is between a thermal expansion coefficient (7.8×10⁻⁶/K to 8.5×10⁻⁶/K) of aluminum oxide at 800° C. and a thermal expansion coefficient (4.1×10⁻⁶/K) of silicon carbide at 800° C.

As the high thermal conductive material in the temperature control member, a material that can reduce a difference in thermal expansion rate between the dielectric substrate 11 and the base 3 may be selected in consideration of the thermal expansion coefficient of the conductive material to be combined. For example, when a material having a higher thermal expansion coefficient than aluminum oxide is used as the conductive material in the temperature control member, a material having a lower thermal expansion coefficient than aluminum oxide, for example, AlN is preferable as the high thermal conductive material to be combined. The thermal expansion coefficient of AlN at 40° C. to 800° C. is considered to be 5.2×10⁻⁶/K.

The base 3 is preferably formed of a conductive ceramic formed of AlN and TiN (thermal expansion coefficient at 900° C.: 7.75×10⁻⁶/K), that is, an AlN—TiN composite sintered body as a forming material. In addition, the base 3 is also preferably formed of a conductive ceramic formed of SiC and TiN, that is, a SiC—TiN composite sintered body as a forming material.

The thermal expansion coefficient of the material of the base 3 at 800° C. is preferably 6.0×10⁻⁶/K or higher and 9.0×10⁻⁶/K or lower. By setting the thermal expansion coefficient of the material of the base 3 to be in the above-described range, a difference in thermal expansion from the dielectric substrate 11 mainly including aluminum oxide is likely to be reduced, and when the electrostatic chuck member 2 and the base 3 are joined, strain is not likely to be generated at an interface between the electrostatic chuck member 2 and the base 3. In addition, when the electrostatic chuck device 1A is used at a high temperature or at a low temperature, strain is not likely to be generated at an interface between the electrostatic chuck member 2 and the base 3. The thermal expansion coefficient of the material of the base 3 at 800° C. may be 6.5×10⁻⁶/K or higher and 8.5×10⁻⁶/K or lower, 6.8×10⁻⁶/K or higher and 8.3×10⁻⁶/K or lower, or 7.0×10⁻⁶/K or higher and 8.0×10⁻⁶/K or lower as necessary.

The base 3 may include one or more sintering additives as necessary within a range where the effect of the present invention is not inhibited. The amount or kind of the sintering additive is not particularly limited as long as the sintering additive is generally added, and examples thereof include Y₂O₃, MgO, SiO₂, CaO, La₂O₃, Ce₂O₃, YOF, and YF₃. Among these, Y₂O₃, MgO, SiO₂, or YF₃ is preferable.

A volume resistivity of the base 3 can be freely selected, and is preferably 1.0×10⁻³ Ω·cm or lower. By setting the volume resistivity of the base 3 to be in the above-described range, sufficient conductivity can be obtained. The volume resistivity of the base 3 is preferably low, and the lower limit value thereof may be, for example, 1.0×10⁻¹⁰ Ω·cm or higher. In addition, the volume resistivity of the base 3 may be 1.0×10⁻⁸ (2·cm or higher and 1.0×10⁻⁴ Ω·cm or lower or 1.0×10⁻⁶ Ω·cm or higher and 1.0×10⁵ Ω·cm or lower as necessary. The volume resistivity of the base 3 may be 1.0×10⁻⁶ Ω·cm or higher and 1.0×10⁻⁵ Ω·cm or lower, 1.0×10⁻⁵ Ω·cm or higher and 1.0×10⁻⁴ Ω·cm or lower, or 1.0×10⁻⁴ Ω·cm or higher and 1.0×10⁻³ Ω·cm or lower.

The thermal expansion coefficient of the material of the base 3 at 800° C. preferably has the same value as the dielectric substrate 11. An absolute value of a difference between the thermal expansion coefficient of the material of the base 3 at 800° C. and the thermal expansion coefficient of the material of the dielectric substrate 11 at 800° C. is preferably 2.5×10⁻⁶/K or lower, more preferably 1.5×10⁻⁶/K or lower, still more preferably 1.3×10⁻⁶/K or lower, and still more preferably 1.0×10⁻⁶/K or lower.

In order to improve plasma resistance, it is preferable that an alumina sprayed film is provided on a surface of the base 3 as necessary.

A hole portion 17 is provided on the base 3. The hole portion 17 extends in the up-down direction. The hole portion 17 penetrates the base 3 in the up-down direction, and is formed on each of the support surface 3a and the lower surface 3b of the base 3. The hole portion 17 has, for example, a circular shape or a substantially circular shape in a plan view. The insulator 23 described below is preferably inserted into the hole portion 17. FIG. 1 illustrates that the hole portion 17 penetrates the base 3 in the up-down direction. As long as the hole portion 17 is formed in at least the support surface 3a such that the insulator 23 is inserted into the hole portion 17, the hole portion 17 does not need to penetrate the base 3.

### (Method of Manufacturing Conductive Ceramic)

The conductive ceramic that is the material of the base 3 can be manufactured using any freely selected method. For example, the high thermal conductive material and the conductive material can be mixed in a predetermined range to obtain raw material powder, and a ceramic can be manufactured with a well-known method using the obtained raw material powder to obtain the conductive ceramic. In a specific example of the manufacturing method, the conductive ceramic can be manufactured through a step of mixing the high thermal conductive material and the conductive material at a freely selected volume ratio, for example, 10:90 to 90:10 or 30:70 to 60:40 to obtain raw material powder, a step of applying a pressure to the obtained raw material powder to obtain a compact, and a step of pressure-sintering the obtained compact to obtain a conductive ceramic. By processing the obtained conductive ceramic in a shape of the base 3, the base 3 according to the present embodiment can be obtained.

An average primary particle diameter of the high thermal conductive material is not particularly limited as long as the conductive ceramic can be obtained. For example, a high thermal conductive material having an average primary particle diameter of 0.5 μm or more and 5 μm or less can be used. The average primary particle diameter may be 1.0 μm or more and 5.0 μm or less or 2.0 μm or more and 4.0 μm or less.

An average primary particle diameter of the conductive material is not particularly limited as long as the conductive ceramic can be obtained. For example, a conductive material having an average primary particle diameter of 0.5 μm or more and 5 μm or less can be used. The average primary particle diameter may be 1.0 μm or more and 5.0 μm or less or 2.0 μm or more and 4.0 μm or less.

In the mixing step, a mixing method is not particularly limited as long as the high thermal conductive material and the conductive material can be mixed to obtain raw material powder. It is preferable that the high thermal conductive material and the conductive material are appropriately mixed with a dispersant or a solvent as necessary to be mixed using a mixing device such as a disperser such that they do not aggregate. The mixing device is not particularly limited, and a general device such as a ball mill, a planetary mill, a beads mill, or an atomizer can be used.

A drying step may be provided after the mixing step. As the drying method, natural drying may be used, a dryer may be used, or granules having a particle diameter of 30 to 100 μm may be formed from the raw material powder using spray-drying.

After the mixing step or after the drying step, the raw material powder may be placed in a non-oxidative atmosphere. For example, the raw material powder may be heated in a non-oxidative atmosphere at a freely selected temperature, for example, 300° C. or higher and 600° C. or lower to remove impurities such as water, the solvent, or the dispersant in the raw material powder.

As the non-oxidative atmosphere, an inert gas atmosphere using nitrogen or argon is preferable. Further, in a case where the heating is performed in an inert gas atmosphere, the heating treatment by a so-called gas flow, in which an atmosphere gas is caused to flow, is preferable in order to efficiently discharge the generated impurities to the outside of the system.

In the molding step, depending on the desired shape of the conductive ceramic, a pressure is applied to the obtained raw material powder using a freely selected molding method such as a metallic molding method, and preferably, uniaxial molding (uniaxial pressing) is performed to obtain a compact having a desired shape.

In the pressure-sintering step, the compact obtained in the molding step is heated and pressure-sintered preferably in a vacuum or in a non-oxidative atmosphere at a freely selected temperature, preferably, 1600° C. or higher while being pressed at a freely selected pressure, preferably, 5 MPa or higher. With the above-described operation, the sintering of the high thermal conductive material or the conductive material in the compact progresses, and a dense sintered body having a small number of pores is obtained. The temperature can be selected as necessary, and may be 1600 to 1900° C., 1650 to 1800° C., or the like. The heating time can be freely selected, and may be, for example, 1 to 5 hours, 3 to 8 hours, or 6 to 12 hours.

Through the above-described steps, the conductive ceramic can be obtained, and by processing the obtained conductive ceramic, the base 3 can be obtained. A method of processing the obtained conductive ceramic can be freely selected. For example, a plurality of members having a freely selected shape may be combined to form the base 3.

### <Joining Layer>

The joining layer 4 joins the electrostatic chuck member 2 and the base 3 to each other. A material of the joining layer 4 can be freely selected. For example, a well-known material used for joining the electrostatic chuck member 2 and the base 3 can be adopted. For example, the material may be a silicone resin, may be a silicone resin including a high thermal conductive filler such as aluminum nitride particles or surface-coated aluminum nitride particles, or may be an inorganic material such as a metal material. From the viewpoint of controlling the temperature of the electrostatic chuck unit 2, the material of the joining layer 4 is preferably an inorganic material.

### (Material of Joining Layer: Inorganic Material 1)

In a case where the inorganic material that is the material of the joining layer 4 is a metal, when the total volume of the joining layer 4 is represented by 100% by volume, it is preferable that the material of the joining layer 4 is an alloy including 50% by volume or more and 99.98% by volume or less of Al or Ag and 0.02% by volume or more and 40% by volume or less of at least one metal selected from the group consisting of Ti, Zr, and Hf. The proportion of Al or Ag may be, for example, 55% by volume or more and 95% by volume or less, 65% by volume or more and 90% by volume or less, 70% by volume or more and 80% by volume or less, or the like. The joining layer 4 includes at least one metal selected from the group consisting of Ti, Zr, and Hf. As a result, when the electrostatic chuck member 2 and the base 3 are joined, a molten alloy obtained by melting the material of the joining layer 4 is likely to wet and spread on the surface of the ceramic (electrostatic chuck member 2), which facilitates joining. In addition, since the joining layer 4 includes the above-mentioned metal, the above-mentioned metal and the ceramic (electrostatic chuck member 2) are likely to adhere to each other, the occurrence of a void at the interface can be suppressed, and strong joining can be achieved.

The thickness of the joining layer 4 can be freely selected, and is preferably 5 μm or more and 500 μm or less. The thickness may be 5 μm or more and 30 μm or less, 30 μm or more and 100 μm or less, 10 μm or more and 300 μm or less, or the like.

When the electrostatic chuck device 1A is manufactured, for example, a metal foil may also be used as the material for forming the joining layer 4, or a metal paste where a binder is added to metal powder may also be used. These materials are disposed between the electrostatic chuck member 2 and the base 3, and are heated to a temperature that is higher than or equal to a melting point of the metal material for forming the joining layer 4 such that the molten metal material wets and spreads between the electrostatic chuck member 2 and the base 3. As a result, the joining layer 4 can be formed.

The forming material of the base 3 is the conductive ceramic such that, when the base 3 and the electrostatic chuck member 2 are joined (brazed) through the metal material, formation of cracks can be suppressed. A mechanism where the formation of cracks during brazing is suppressed by using the conductive ceramic as the forming material of the base 3 is presumed to be as follows.

The material for forming the base needs to have excellent thermal conductivity, electrical conductivity, and workability. Therefore, in the related art, the base is formed of a metal such as aluminum. On the other hand, the dielectric substrate forming the electrostatic chuck member is formed of a ceramic as a forming material. In general, the thermal expansion coefficient of the ceramic is significantly lower than the thermal expansion coefficient of the metal. Therefore, a difference in thermal expansion coefficient between a base in the related art formed of a metal and an electrostatic chuck member formed of a ceramic as a forming material is large.

For example, when the material of the base is aluminum, the melting point of aluminum is about 660° C., and thus the thermal expansion coefficient at 800° C. is not present. However, the thermal expansion coefficient (20° C. to 100° C.) of the material of the base is about 24×10⁻⁶/K. On the other hand, when the main component of the material of the dielectric substrate 11 forming the electrostatic chuck member 2 is aluminum oxide, the thermal expansion coefficient of the material of the dielectric substrate 11 (25° C. to 800° C.) is the same as the thermal expansion coefficient of the aluminum oxide (7.8×10⁻⁶/K to 8.5×10⁻⁶/K). That is, when the material of the base is aluminum and the main component of the material of the dielectric substrate 11 is aluminum oxide, the thermal expansion coefficient of the material of the dielectric substrate 11 is lower than the thermal expansion coefficient of the material of the base.

The joining (brazing) in the metal material is performed at a high temperature (for example, 800° C.) of 500° C. or higher. Therefore, during brazing, both of the base and the electrostatic chuck member are at a high temperature. At this time, when the base formed of the metal is used, it is considered that, in the joining layer (the layer of the brazing material) where the base formed of a metal and the dielectric substrate 11 (electrostatic chuck member) formed of a ceramic as a forming material are joined, tensile stress is generated based on the difference in thermal expansion coefficient between both of the materials. Due to this stress, cracks may be formed in the electrostatic chuck member.

On the other hand, the base 3 that is adopted in the electrostatic chuck device 1A according to the present embodiment is formed of the conductive ceramic as a forming material. Therefore, a difference in thermal expansion coefficient between the material of the base 3 and the material of the dielectric substrate 11 formed of a ceramic is smaller than that of the base formed of a metal. The base 3 includes the high thermal conductive material, and thus has a sufficiently high thermal conductivity. In addition, the base 3 includes the conductive material, and thus has a sufficiently high conductivity. Therefore, during brazing between the electrostatic chuck member 2 and the base 3, the tensile stress generated from the joining layer 4 is reduced, and heat can also be effectively dissipated after the joining. Therefore, in the electrostatic chuck device 1A according to the present embodiment, the formation of cracks in the electrostatic chuck member 2 can be suppressed.

Further, in the electrostatic chuck device 1A formed as described above, the joining layer 4 is preferably formed of a metal material (brazing material). Therefore, even in the joining layer 4, heat can be effectively dissipated. Therefore, in the electrostatic chuck device 1A, the wafer W, the dielectric substrate 11, the joining layer 4, and the base 3 can be made to have a low temperature with respect to plasma input heat, and a stable temperature control can be performed.

### (Material of Joining Layer: Inorganic Material 2)

In a case where the inorganic material that is the material of the joining layer 4 is not a metal, the material in the electrostatic chuck member 2 or the base 3 can be used as the material of the joining layer 4. For example, the insulating material in the dielectric substrate 11 forming the electrostatic chuck member 2, or the high thermal conductive material or the conductive material in the base 3 can be used as necessary. By forming the joining layer using the material in the electrostatic chuck member 2 and the base 3, the electrostatic chuck member 2 and the base 3 can be joined to each other. The joining layer 4 may include a binder component as long as the effect of the present invention is not inhibited. However, it is preferable that the joining layer 4 does not include the binder component. For example, when the forming material of the joining layer 4 may include the binder, and the formed joining layer 4 may include no or substantially no binder.

The inorganic material that is the material of the joining layer 4 may include the insulating material in the dielectric substrate 11 forming the electrostatic chuck member 2 and at least one of the high thermal conductive material and the conductive material in the base 3. The joining layer 4 may include a binder component as long as the effect of the present invention is not inhibited. However, it is preferable that the joining layer 4 does not include the binder component.

In this case, the joining layer 4 can be formed using a joining material (described below) including the insulating material and at least one of the high thermal conductive material and the conductive material. When the joining layer 4 is desired to be insulating, the joining material may include the high thermal conductive material without including the conductive material. When the joining layer 4 is desired to be conductive, the joining material may include the conductive material.

As the binder component, for example, a resin material can be used.

As the resin material, a resin that is not likely to cause cohesive failure due to thermal stress is preferable, and examples thereof include a silicone resin, an acrylic resin, an epoxy resin, a phenol resin, a polyurethane resin, and an unsaturated polyester resin. Among these, a silicone resin is preferable from the viewpoints that the degree of expansion and contraction is high and cohesive failure caused by a change in thermal stress is not likely to occur.

As the binder component, a volatile binder component is preferably used such that the binder component does not remain after joining the layers.

A ratio between the insulating material and at least one of the high thermal conductive material and the conductive material in the joining layer 4 is not particularly limited as long as the electrostatic chuck member 2 and the base 3 are joined. Hereinafter, “at least one of the high thermal conductive material and the conductive material” will also be abbreviated as “high thermal conductive material or the like”.

In the manufactured electrostatic chuck device 1A, when an interface between the joining layer 4 and the electrostatic chuck member 2 is likely to be peeled off, the ratio of the insulating material in the joining layer 4 may be increased. In the electrostatic chuck device 1A, when an interface between the joining layer 4 and the base 3 is likely to be peeled off, the content of the high thermal conductive material or the like in the joining layer 4 may be increased.

In the joining layer 4, a volume ratio between the insulating material and the high thermal conductive material or the like can be freely selected, and may be, for example, 2:1 to 1:2 or 1:1 to 2:1.

The content of the binder component in the joining layer 4 is not particularly limited as long as the electrostatic chuck member 2 and the base 3 are joined. In order to facilitate heat transfer in the joining layer 4, it is preferable that the joining layer 4 does not include the binder component. The joining layer 4 may include, for example, 1% by mass or more and 50% by mass or less of the binder component, 10% by mass or more and 45% by mass or less of the binder component, or 20% by mass or more and 40% by mass or less of the binder component.

The thickness of the joining layer 4 can be freely selected and is preferably 1 μm or more and 50 μm or less, more preferably 5 μm or more and 30 μm or less, and still more preferably 10 μm or more and 20 μm or less.

The material (joining material) of the joining layer 4 may be, for example, a paste-like composition obtained by mixing the insulating material in the electrostatic chuck member 2 and the high thermal conductive material or the like in the base 3. The joining layer 4 is formed between the electrostatic chuck member 2 and the base 3 by stacking the electrostatic chuck member 2 and the base 3 through a coating film of the joining material and subsequently pressurizing and heating the stacked body (pressurization and heating) in a vacuum or in a non-oxidative atmosphere.

The obtained joining layer 4 includes the insulating material that is the material of the electrostatic chuck member 2. Therefore, the joining layer 4 and the electrostatic chuck member 2 are preferably joined by the pressurization and heating.

Likewise, the obtained joining layer 4 includes the high thermal conductive material or the like that is the material of the base 3. Therefore, the base 3 and the joining layer 4 are preferably joined by the pressurization and heating.

As a result, the electrostatic chuck member 2 and the base 3 are joined through the joining layer 4.

The coating film of the joining material can be formed using a freely selected method or condition and, for example, may be formed by applying the joining material to at least one of the electrostatic chuck member 2 and the base 3 such that the dried film thickness is 1 μm or more and 50 μm or less.

Conditions of the pressurization and heating are not particularly limited as long as the electrostatic chuck member 2 and the base 3 can be joined. For example, it is preferable that a heat treatment is performed at a pressure of 5 MPa or higher and 1600° C. to 1800° C. for several hours.

The material of the joining layer 4 is the inorganic material such that heat can be effectively removed from the base 3 in addition to the effect of the present invention.

It was verified by simulation that, in the base 3 having the above-described configuration, heat input to the dielectric substrate 11 can be transferred and effectively dissipated.

In the simulation, an Al₂O₃—SiC composite sintered body was used as the dielectric substrate 11, and the effect of heat transfer of the base 3 was verified for an electrostatic chuck device A where the base 3 was aluminum and an electrostatic chuck device B where the base 3 was an AlN—TiN composite sintered body. The simulation was performed assuming that, as the material of the joining layer 4, a silicone adhesive was used for the electrostatic chuck device A and a metal brazing material (Ag) was used for the electrostatic chuck device B.

In the simulation, a thermal conductivity per unit thickness of each of the layers was calculated from a thickness and a thermal conductivity of the material of each of the layers. In addition, when a given amount of heat was input to a wafer and a coolant at −70° C. was allowed to flow through a flow channel, a wafer temperature and a temperature of each of the layers were calculated.

As a result, when a temperature of the joining layer 4 in the electrostatic chuck device A was represented by T° C., a temperature of the joining layer 4 in the electrostatic chuck device B was T-50° C. In addition, temperatures of the dielectric substrate 11, a wafer W, and a contact portion between the wafer W and the dielectric substrate 11 in the electrostatic chuck device B were 50° C. lower than those in the electrostatic chuck device A. That is, it was verified that, by changing the forming material of the base 3 from metal in the related art to the conductive ceramic, plasma heat can be effectively dissipated (removed).

In addition, by verifying the temperature of each of the layers in detail, it was verified that heat transfer in the joining layer of the electrostatic chuck device A was inhibited.

In terms of only the performance of heat removal, the electrostatic chuck device B including the base formed of the conductive ceramic was considered to be more disadvantageous than the electrostatic chuck device A including the base formed of the metal material. However, for the base formed of the conductive ceramic, the joining layer formed of the inorganic material having high thermal conductivity can be suitably adopted. Therefore, it is considered that, in the electrostatic chuck device B, heat input to the dielectric substrate 11 can be transferred and more effectively dissipated comprehensively as compared to the electrostatic chuck device A. In addition, it is considered that the electrostatic chuck device B is advantageous in that strain is not likely to occur.

### <Other Configuration>

### (Supporting Plate)

The supporting plate 5 preferably supports the base 3 from the lower surface 3b of the base 3. It is preferable that the supporting plate 5 is formed of a material having a higher Young's modulus than the material of the base 3. For example, as the material of the supporting plate 5, any one of a metal, MMC, and a ceramic can be adopted. In particular, as the supporting plate 5, a ceramic plate such as Al₂O₃ having a higher Young's modulus than the base 3 is preferable.

The ceramic used for the supporting plate 5 is preferably the same as the material used for the electrostatic chuck member 2. Specific examples of the ceramic include aluminum oxide, aluminum nitride, and an Al₂O₃—SiC composite sintered body. By using the same material for the supporting plate 5 and the electrostatic chuck member 2, a difference in thermal expansion coefficient between the materials of the supporting plate 5 and the electrostatic chuck member 2 can be reduced, and warpage of the electrostatic chuck device 1A is suppressed.

### (Insulator)

The insulator 23 is inserted into the hole portion 17 to be assembled into the base 3. That is, the insulator 23 functions as an insertion component to be inserted into the hole portion 17. The insulator 23 has a cylindrical shape extending in the up-down direction. In the insulator 23, the feeding terminal 16 is disposed. An outer peripheral surface of the insulator 23 is joined to an inner side surface of the hole portion 17 using joining means such as adhesion. The insulator 23 insulates the base 3 formed of a metal and the feeding terminal 16 from each other.

The insulator 23 is formed of, for example, a ceramic as a forming material. That is, the insulator 23 is preferably formed of an insulating member. As a result, the insulator 23 can suppress a phenomenon in which a gas introduction hole causes abnormal discharge to occur. The insulator 23 has durability against a plasma. As the ceramic forming the insulator 23, a ceramic including one or two or more selected from AlN, Al₂O₃, Si₃N₄, zirconium oxide (ZrO₂), sialon, boron nitride (BN), and SiC can be adopted.

An end surface (hereinafter, an upper end surface 23a) of the insulator 23 on the upper side is in contact with the electrostatic chuck member 2 or is disposed with an insulating adhesive interposed between the end surface and the electrostatic chuck member 2.

### (Feeding Terminal)

The feeding terminal 16 extends downward from the adsorption electrode 13. The feeding terminal 16 is connected to an external power supply 21. The power supply 21 applies a voltage to the adsorption electrode 13. The number, shape, and the like of the feeding terminals 16 are determined depending on the form of the adsorption electrode 13, that is, whether the adsorption electrode 13 is unipolar or bipolar.

The feeding terminal 16 is allowed to pass through a first hole 17a of the dielectric substrate 11, a second hole 17b of the joining layer 4, and a third hole 17c of the supporting plate 5. The first hole 17a is provided on a portion below the adsorption electrode 13 of the dielectric substrate 11.

Each of the first hole 17a, the second hole 17b, and the third hole 17c has a circular shape or a substantially circular shape when seen from the stacking direction. The first hole 17a, the second hole 17b, and the third hole 17c communicate with the hole portion 17 of the base 3. In addition, inner peripheral surfaces of the first hole 17a, the second hole 17b, and the third hole 17c lie next to an inner peripheral surface of the insulator 23 when seen from the stacking direction. Inner diameters of the first hole 17a, the second hole 17b, and the third hole 17c are substantially the same as an inner diameter of the insulator 23, and are slightly larger than an outer diameter of the feeding terminal 16.

According to the above-described base 3 (temperature control member), it is possible to provide a novel temperature control member where strain is not likely to occur, breakage is suppressed, and an excellent temperature control can be performed.

In the electrostatic chuck device having the above-described configuration, by including the temperature control member, it is possible to provide a novel electrostatic chuck device where breakage is suppressed and an excellent temperature control can be performed.

The electrostatic chuck device 1A includes the joining layer 4. By diffusion-joining the electrostatic chuck member 2 and the base 3, the electrostatic chuck member 2 and the base 3 may be directly joined without interposing the joining layer 4.

In addition, in the above-described embodiment, the configuration where the temperature control member is used as the base of the electrostatic chuck device has been described, but the present invention is not limited thereto. For example, the temperature control member for allowing the heating medium as the heat medium to flow can be adopted for a heat exchanger, a heater unit, a battery module, or a nuclear reactor.

### Second Embodiment

FIG. 2 is a diagram illustrating an electrostatic chuck device 1B according to a second embodiment of the present invention. The electrostatic chuck device 1B according to the present embodiment is partially common to the electrostatic chuck device 1A according to the first embodiment. Accordingly, in the present embodiment, components common to those of the first embodiment will be represented by the same reference numerals, and the detailed description will not be made.

The electrostatic chuck device 1B includes the electrostatic chuck member 2, the base 3, a joining layer 6, the supporting plate 5, the insulator (insertion component) 23, and the feeding terminal 16. The electrostatic chuck member 2 and the base 3 are stacked through the joining layer 6.

### (Joining Layer)

The joining layer 6 includes a stress relief layer 61, a first joining layer 62 configured to join the stress relief layer 61 and the electrostatic chuck member 2, and a second joining layer 63 configured to join the stress relief layer 61 and the base 3. The joining layer 6 has a higher thermal conductivity than the base 3. It is preferable that the first joining layer 62, the stress relief layer 61, and the second joining layer 63 are in direct contact with each other. However, the present invention is not limited to only this example.

The stress relief layer 61 is formed of a material that is easily plastically deformable, and relieves thermal stress generated by a difference in thermal expansion rate between the electrostatic chuck member 2 and the base 3. A material of the stress relief layer 61 is preferably a metal foil formed of at least one metal selected from the group consisting of Cu, Al, and Ti.

Alternatively, as the material of the stress relief layer 61, a material having a small difference in thermal expansion coefficient from Al₂O₃ forming the electrostatic chuck member 2 can also be used. Examples of a material that has a small difference in thermal expansion coefficient from the thermal expansion coefficient (7.8×10⁻⁶/K to 8.5×10⁻⁶/K) of Al₂O₃ and is used as the stress relief layer include Ti (8.4×10⁻⁶/K), Nb (7.1×10⁻⁶/K), and W (4.6×10⁻⁶/K). The difference in thermal expansion coefficient being small represents that, for example, the difference may be 4.0×10⁻⁶/K to 0.5×10⁻⁶/K. When the thermal expansion coefficient of the material of the stress relief layer 61 and the thermal expansion coefficient of the material forming the electrostatic chuck member 2 are compared to each other, the comparison may be performed using the thermal expansion coefficients at the same measurement temperature.

The thickness of the stress relief layer 61 can be freely selected, and is preferably 0.1 mm or more and 1 cm or less and more preferably 1 mm or more and 1 cm or less. The thickness may be 0.5 mm or more and 8 mm or less or 2 mm or more and 5 mm or less as necessary. Since the thickness of the stress relief layer 61 is in the above-described range, thermal stress can be sufficiently relieved, and peeling between the electrostatic chuck member 2 and the base 3 can be suppressed.

It is preferable that the materials of the first joining layer 62 and the second joining layer 63 have a lower melting point than the forming material of the stress relief layer. The first joining layer 62 and the second joining layer 63 may be the same material.

As the material of the first joining layer 62, the same material or conditions as those of the joining layer 4 according to the first embodiment can be preferably adopted. That is, when the total volume of the first joining layer 62 is represented by 100% by volume, it is preferable that the material of the first joining layer 62 is an alloy including 50% by volume or more of A1 or Ag and 0.02% by volume or more and 40% by volume or less of at least one metal selected from the group consisting of Ti, Zr, and Hf. For the second joining layer 63, the same material can also be adopted.

The thicknesses of the first joining layer 62 and the second joining layer 63 can be freely selected and, for example, are preferably 0.005 mm or more and 0.5 mm or less.

The joining layer 6 includes the stress relief layer 61 such that stress generated at the interface between the base 3 and the electrostatic chuck member 2 can be relieved, and the peeling of the joining layer 6 can be suppressed.

In the electrostatic chuck device 1B having the above-described configuration, it is possible to provide a novel electrostatic chuck device where breakage is suppressed and an excellent temperature control can be performed.

Hereinabove, the preferred embodiment of the present invention has been described above with reference to the accompanying drawings. However, the present invention is not limited to such an example. The various shapes, combinations, and the like of the constituent members shown in the above examples are merely examples, and various modifications can be made based on design requirements and the like without departing from the gist of the present invention.

### EXAMPLES

Hereinafter, the present invention will be described in detail using Examples and Comparative Examples, but is not limited to the following examples.

The following test pieces were prepared. These test pieces were used in Example 1 and Comparative Example 1 described below.
Dielectric substrate (Al₂O₃: SiC=95:5 (mass ratio), thickness: 2 mm)
Conductive ceramic substrate (AlN: TiN=50:50, thickness: 1 mm)
Aluminum substrate (thickness: 1 mm)

The conductive ceramic substrate was prepared using the following method.

### (Preparation of Conductive Ceramic Substrate)

Using a ball mill including a medium formed of aluminum oxide having a diameter of 1 mm or more and 5 mm or less, a mixture of AlN particles having an average primary particle diameter of 1 μm, TiN particles having an average primary particle diameter of 1 μm, a dispersant, and ethanol was mixed for 12 hours. The AlN particles and the TiN particles were weighed at a volume ratio of 50:50.

Next, the obtained mixed liquid was naturally dried to obtain raw material powder of the conductive ceramic. The obtained raw material powder was heated in a nitrogen atmosphere of 500° C. for 12 hours.

The heated raw material powder was uniaxially pressed at a pressure of 8 MPa using a metallic molding method to obtain a compact. The obtained compact was set to a graphite mold, and was held in a nitrogen atmosphere at a pressure of 20 MPa and 1700° C. for 2 hours for pressure-sintering. As a result, a conductive ceramic substrate was obtained.

The obtained conductive ceramic substrate was processed into a thickness of 1 mm to obtain a test piece of the conductive ceramic substrate.

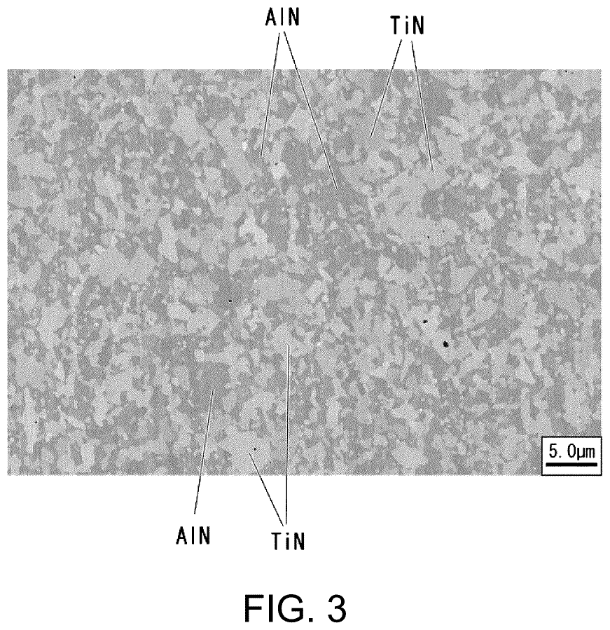

FIG. 3 is a scanning electron microscope (SEM) image illustrating the conductive ceramic plate prepared using the above-described method. More specifically, FIG. 3 is an image obtained by observing the conductive ceramic plate with a field emission scanning electron microscope (FE-SEM) (product name: Merlin, manufactured by Carl Zeiss AG). In FIG. 3, a region indicated by a deeper color is a region occupied by AlN, and a region indicated by a lighter color is a region occupied by TiN. It was verified from FIG. 3 that the conductive ceramic where AlN and TiN were substantially uniformly mixed was obtained.

### Example 1

The dielectric substrate and the conductive ceramic substrate were pressurized at 860° C. and 13 Pa and joined using a metal brazing material (TKC-661, manufactured by TANAKA PRECIOUS METAL TECHNOLOGIES Co., Ltd.). As a result, it was verified that cracks were not formed in both of the dielectric substrate and the conductive substrate such that the dielectric substrate and the conductive substrate were able to be joined without a problem.

### Comparative Example 1

The dielectric substrate and the aluminum substrate were pressurized at 550° C. and 13 Pa and joined using a metal brazing material (TKC-661, manufactured by TANAKA PRECIOUS METAL TECHNOLOGIES Co., Ltd.). As a result, it was verified that the dielectric substrate and the aluminum substrate were able to be joined; however, cracks were formed in the dielectric substrate and this joined body was not suitable for application to the electrostatic chuck device.

Example 1 and Comparative Example 1 were results obtained using the test pieces, and the same behavior was considered to occur at an interface between the electrostatic chuck member 2 formed of the dielectric substrate and the base 3 formed of the conductive ceramic. That is, it is assumed that, when the electrostatic chuck member formed of the dielectric substrate and the base formed of the conductive ceramic defined by the present invention are brazed, cracks are not formed in both of the dielectric substrate and the conductive substrate such that preferable joining can be performed.

### Examples 2 to 8

A conductive ceramic substrate having a composition shown in Table 1 below was prepared to measure a thermal expansion coefficient and a volume resistivity thereof. A conductive ceramic substrate was prepared using the method of (Preparation of Conductive Ceramic Substrate) described above.

That is, the conductive ceramic plate according to Example 2 was prepared using the same method as that of Example 1, except that the AlN particles and the TiN particles were weighed at a volume ratio of 40:60.

The conductive ceramic plate according to Example 3 was prepared using the same method as that of Example 1, except that the AlN particles and the TiN particles were weighed at a volume ratio of 65:35.

The conductive ceramic plate according to Example 4 was prepared using the same method as that of Example 1, except that Mo particles having an average primary particle diameter of 1.5 μm were used instead of the TiN particles having an average primary particle diameter of 1 μm, and the AlN particles and the Mo particles were weighed at a volume ratio of 35:65.

The conductive ceramic plate according to Example 5 was prepared using the same method as that of Example 4, except that the AlN particles and the Mo particles were weighed at a volume ratio of 65:35.

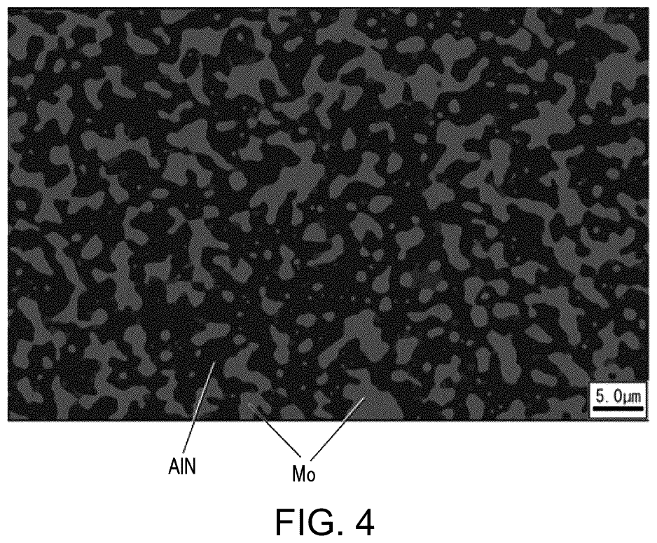

FIG. 4 is a backscattered electron image obtained by observing the conductive ceramic plate according to Example 5 with a field emission scanning electron microscope (FE-SEM) (product name: Merlin, manufactured by Carl Zeiss AG). In FIG. 4, a region indicated by a deeper color is a region occupied by AlN, and a region indicated by a lighter color is a region occupied by Mo. It was verified from FIG. 4 that the conductive ceramic where AlN and Mo were substantially uniformly mixed was obtained.

The conductive ceramic plate according to Example 6 was prepared using the same method as that of Example 1, except that Mo particles having an average primary particle diameter of 1.5 μm were used in addition to the AlN particles and the TiN particles, and the AlN particles, the TiN particles, and the Mo particles were weighed at 29:36:35.

The conductive ceramic plate according to Example 7 was prepared using the same method as that of Example 6, except that the AlN particles, the TiN particles, and the Mo particles were weighed at 36:29:35.

The thermal expansion coefficient and the volume resistivity were measured using the following method.

### (Thermal Expansion Coefficient)

A test piece of 3 mm×3 mm×15 mm was obtained from the obtained conductive ceramic plate. Using this test piece and a thermal expansion measuring device (TD 5000 SA, manufactured by NETZSCH Japan K.K.), a change in the length in the diameter direction when the temperature was changed from 25° C. to 800° C. at a temperature increase rate of 5° C./min was measured to obtain a thermal expansion rate at 25° C. to 800° C. Further, the obtained thermal expansion rate was divided by a temperature change width (AT=800° C.-25° C.=775° C.) to measure a thermal expansion coefficient (/K) at 800° C.

### (Measurement of Volume Resistivity)

A test piece of 3 mm×4 mm×40 mm was obtained from the obtained conductive ceramic substrate. Using this test piece, a four-terminal method according to “JIS C 2525”, an electrical resistance measuring device (TER-2000RH, manufactured by ADVANCE RIKO, Inc.), a volume resistivity ((Ω·cm) was measured. Measurement conditions are as follows.
Measurement temperature: room temperature (22° C.).
Measurement current: 2.0 A
Distance between voltage terminals: 31 mm

The measurement results are shown in Table 1. Both of “A: B” and “B1: B2” of Table 1 represent the volume ratios.

TABLE 1

| | | Example 1 | Example 2 | Example 3 | Example 4 | Example 5 | Example 6 | Example 7 |
|---|---|---|---|---|---|---|---|---|
| Material A | | AlN | | | | | | |
| Material B | B1 | TiN | TiN | TiN | Mo | Mo | TiN | TiN |
| | B2 | — | — | — | — | — | Mo | Mo |

| | | | | | | | |
|---|---|---|---|---|---|---|---|
| A:B | 50:50 | 40:60 | 65:35 | 35:65 | 65:35 | 29:71 | 36:64 |
| B1:B2 | — | — | — | — | — | 36:35 | 29:35 |
| Thermal Expansion | 7.0 | 7.5 | 6.2 | 5.9 | 5.4 | 7.0 | 6.5 |
| Coefficient | | | | | | | |
| (ppm/K) | | | | | | | |
| Volume Resistivity | 1.4 × 10⁻⁴ | 5.4 × 10⁻⁵ | 2.9 × 10⁻⁴ | 1.7 × 10⁻⁵ | 9.7 × 10⁻⁵ | 2.2 × 10⁻⁵ | 2.9 × 10⁻⁵ |
| (Ω · cm) | | | | | | | |

Material A: High Thermal Conductive Material, Materials B1, B2: Conductive Material

In A1 (aluminum) generally used as a material of the temperature control member, the thermal expansion coefficient was 24 ppm/K, and the volume resistivity was 2.7×10⁻⁶ Ω·cm. It was verified that all of the conductive ceramics according to Examples 1 to 7 had lower thermal expansion coefficients than A1 and had sufficient conductivity compared to A1.

From the above results, it was verified that the present invention is useful.

### REFERENCE SIGNS LIST

1A, 1B electrostatic chuck device
2 electrostatic chuck member
2a placement surface
2b back surface
3 base
3a support surface
3b lower surface
3f flow channel
4, 6 joining layer
5 supporting plate
11 dielectric substrate
13 adsorption electrode
16 feeding terminal
17 hole portion of base
17a first hole
17b second hole
17c third hole
22 high-frequency power supply
23 insulator
23a upper end surface
61 stress relief layer
62 first joining layer
63 second joining layer

1. A temperature control member that is formed of a conductive ceramic as a forming material, comprising:
a flow channel through which a heat medium flows,
wherein the conductive ceramic is formed of a high thermal conductive material and a conductive material, and a volume ratio between the high thermal conductive material and the conductive material is 10:90 to 90:10, and
a thermal expansion coefficient of the conductive ceramic at 800° C. is 10×10⁻⁶/K or lower.

2. The temperature control member according to claim 1,
wherein the high thermal conductive material is at least one selected from the group consisting of AlN, SiC, GaN, SiO₂, Al₂O₃, SmAlO₃, MgO, Si₃N₄, Al(OH)₃, Mg(OH)₂, BN, ZnO, BeO, B₄C, carbon, aluminum, copper, silver, and gold, and
the conductive material is at least one selected from the group consisting of SiC, TiO₂, TiN, TiC, W, WC, Mo, MOC, Mo₂C, TaC, TaN, NbC, VC, and C.

3. The temperature control member according to claim 2,
wherein the high thermal conductive material is AlN, and the conductive material is TiN.

4. The temperature control member according to claim 2,
wherein the high thermal conductive material is AlN, and the conductive material is Mo.

5. The temperature control member according to claim 2,
wherein the high thermal conductive material is AlN, and the conductive material is TiN and Mo.

6. An electrostatic chuck device comprising:
the temperature control member according to claim 1; and
an electrostatic chuck member that is supported by the temperature control member and includes a dielectric substrate and an internal electrode.
